(19) United States
(12) Patent Application Publication
(10) Pub. No.: US 2025/0309165 A1
(43) Pub. Date: Oct. 2, 2025

(54) MANAGING PERIPHERAL CIRCUITRIES IN SEMICONDUCTIVE DEVICES

(71) Applicant: Yangtze Memory Technologies Co., Ltd., Wuhan, Hubei (CN)

(72) Inventors: Zongliang HUO, Wuhan (CN); Danyang WEI, Wuhan (CN); Zichen LIU, Wuhan (CN); Yanhong WANG, Wuhan (CN); Liang CHEN, Wuhan (CN); Wei LIU, Wuhan (CN)

(21) Appl. No.: 18/767,932

(22) Filed: Jul. 9, 2024

(30) Foreign Application Priority Data
Mar. 26, 2024 (CN) 202410355095.2

(51) Int. Cl. H01L 23/00; H01L 21/768; H01L 23/48; H10B 12/00; H10B 80/00

(52) U.S. Cl. CPC H01L 24/08; H01L 21/76898; H01L 23/481; H01L 24/80; H10B 12/30; H10B 80/00; H01L 2224/08145; H01L 2224/80895; H01L 2224/80896

(57) ABSTRACT

Systems, devices, methods for managing peripheral circuitries in semiconductor devices are provided. In one aspect, a semiconductor device includes a first semiconductor structure that includes a memory array and a first circuitry coupled to the memory array and a second semiconductor structure that includes a second circuitry. The first semiconductor structure includes a first bonding layer, and the second semiconductor structure includes a second bonding layer. The first bonding layer and the second bonding layer are in contact with each other. The first circuitry and the second circuitry are coupled together.

### CROSS-REFERENCE TO RELATED APPLICATIONS

This application claims priority to Chinese Patent Application No. 202410355095.2, filed on Mar. 26, 2024, which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory DRAMs. The semiconductor memory devices can have various structures to increase a density of memory cells and lines on a chip. A memory device normally includes a memory array of memory cells and peripheral circuitries for facilitating operations of the memory array.

### SUMMARY

The present disclosure describes methods, devices, systems and techniques for managing peripheral circuitries in semiconductor devices.

One aspect of the present disclosure features a semiconductor device, including: a first semiconductor structure includes a memory array and a first circuitry coupled to the memory array. A second semiconductor structure includes a second circuitry. The first semiconductor structure includes a first bonding layer and the second semiconductor structure includes a second bonding layer. The first bonding layer and the second bonding layer are in contact with each other. The first circuitry and the second circuitry are coupled together.

In some implementations, the first circuitry and the first bonding layer are in a first side of the first semiconductor structure. The second circuitry and the second bonding layer are in a first side of the second semiconductor structure.

In some implementations, the second semiconductor structure includes a semiconductor substrate, and the second circuitry is on a first side of the semiconductor substrate. The semiconductor device further includes a conductive interconnection structure on a second side of the semiconductor substrate that is opposite to the first side of the semiconductor substrate. The first circuitry is connected to the conductive interconnection structure by a first conductive structure extending through the semiconductor substrate, the first bonding layer, and the second bonding layer. The second circuitry is connected to the conductive interconnection structure by a second conductive structure extending through the semiconductor substrate. The first conductive structure and the second conductive structure are connected by the conductive interconnection structure.

In some implementations, the first bonding layer includes one or more first conductive contacts isolated by a first dielectric material. The second bonding layer includes one or more second conductive contacts isolated by a second dielectric material. At least one of the one or more first conductive contacts is in contact with a corresponding one of the one or more second conductive contacts.

In some implementations, the second semiconductor structure includes a semiconductor substrate, and the second circuitry is on a first side of the semiconductor substrate. The semiconductor device further includes a conductive interconnection structure on a second side of the semiconductor substrate that is opposite to the first side of the semiconductor substrate. The second circuitry is connected to the conductive interconnection structure by a conductive structure extending through the semiconductor substrate. The first circuitry and the second circuitry are connected by the at least one of the one or more first conductive contacts and the corresponding one of the one or more second conductive contacts.

In some implementations, the memory array and the first circuitry are arranged in the first side of the first semiconductor structure along a first direction. The semiconductor device further includes a conductive interconnection structure on a second side of the first semiconductor structure that is opposite to the first side of the first semiconductor structure along a second direction perpendicular to the first direction, and one or more conductive structures extending in the first semiconductor structure from the conductive interconnection structure towards the first side of the second semiconductor structure.

In some implementations, the first semiconductor structure includes a first conductive contact having a first end connected to a corresponding second conductive contact of the one or more second conductive contacts and a second end connected to a corresponding conductive structure of the one or more conductive structures.

In some implementations, a memory cell of the memory array includes a transistor and a capacitor. The transistor includes a gate as at least part of a word line, a first terminal coupled to a bit line, and a second terminal coupled to the capacitor. The bit line and the capacitor are on a same side of the word line.

In some implementations, the first circuitry includes at least one of a sense amplifier coupled to a corresponding bit line or a word line driver coupled to a corresponding word line. The second circuitry includes an input-output (I/O) circuitry configured to communicate with one or more external devices.

Another aspect of the present disclosure features a semiconductor device including: a first semiconductor structure includes a memory array and a first circuitry coupled to the memory array. A second semiconductor structure includes a second circuitry. The first circuitry and the second circuitry are coupled together. A memory cell of the memory array includes a transistor and a capacitor. The transistor includes a gate as at least part of a word line, a first terminal coupled to a bit line, and a second terminal coupled to the capacitor. The bit line and the capacitor are on a same side of the word line.

In some implementations, the first semiconductor structure includes a first bonding layer and the second semiconductor structure includes a second bonding layer. The first circuitry and the first bonding layer are in a first side of the first semiconductor structure. The second circuitry and the second bonding layer are in a first side of the second semiconductor structure. The first bonding layer and the second bonding layer are in contact with each other. The first bonding layer, the bit line, and the capacitor are on the same side of the word line.

In some implementations, the second semiconductor structure includes a semiconductor substrate, and the second circuitry is on a first side of the semiconductor substrate. The semiconductor device further includes a conductive interconnection structure on a second side of the semiconductor substrate that is opposite to the first side of the semiconductor substrate. The first circuitry is connected to the conductive interconnection structure by a first conductive structure extending through the semiconductor substrate, the first bonding layer, and the second bonding layer. The second circuitry is connected to the conductive interconnection structure by a second conductive structure extending through the semiconductor substrate. The first conductive structure and the second conductive structure are connected by the conductive interconnection structure.

In some implementations, the first bonding layer includes one or more first conductive contacts isolated by a first dielectric material. The second bonding layer includes one or more second conductive contacts isolated by a second dielectric material. At least one of the one or more first conductive contacts is in contact with a corresponding one of the one or more second conductive contacts.

In some implementations, the second semiconductor structure includes a semiconductor substrate, and the second circuitry is on a first side of the semiconductor substrate. The semiconductor device further includes a conductive interconnection structure on a second side of the semiconductor substrate that is opposite to the first side of the semiconductor substrate. The second circuitry is connected to the conductive interconnection structure by a conductive structure extending through the semiconductor substrate. The first circuitry and the second circuitry are connected by the at least one of the one or more first conductive contacts and the corresponding one of the one or more second conductive contacts.

In some implementations, the memory array and the first circuitry are arranged in the first side of the first semiconductor structure along a first direction. The semiconductor device further includes: a conductive interconnection structure on a second side of the first semiconductor structure that is opposite to the first side of the first semiconductor structure along a second direction perpendicular to the first direction, and one or more conductive structures extending in the first semiconductor structure from the conductive interconnection structure towards the first side of the second semiconductor structure.

Another aspect of the present disclosure features a method including: providing a first semiconductor structure including a memory array and a first circuitry coupled to the memory array. The first semiconductor structure includes a first bonding layer. Providing a second semiconductor structure include a second circuitry. The second semiconductor structure includes a second bonding layer. Integrating the first semiconductor structure and the second semiconductor structure by bonding the first bonding layer and the second bonding layer to be in contact with each other and coupling the first circuitry and the second circuitry together.

In some implementations, the second semiconductor structure includes a semiconductor substrate, and the second circuitry is formed on a first side of the semiconductor substrate. The method further includes: forming a conductive interconnection structure on a second side of the semiconductor substrate that is opposite to the first side of the semiconductor substrate. Forming a first conductive structure extending through the semiconductor substrate, the first bonding layer, and the second bonding layer to connect the first circuitry to the conductive interconnection structure. Forming a second conductive structure extending through the semiconductor substrate to connect the second circuitry to the conductive interconnection structure. Coupling the first circuitry and the second circuitry together includes: connecting the first conductive structure and the second conductive structure through the conductive interconnection structure.

In some implementations, the first bonding layer includes one or more first conductive contacts isolated by a first dielectric material. The second bonding layer includes one or more second conductive contacts isolated by a second dielectric material. At least one of the one or more first conductive contacts is in contact with a corresponding one of the one or more second conductive contacts.

In some implementations, the second semiconductor structure includes a semiconductor substrate, and the second circuitry is on a first side of the semiconductor substrate. The method further includes: forming a conductive interconnection structure on a second side of the semiconductor substrate that is opposite to the first side of the semiconductor substrate. Forming a conductive structure extending through the semiconductor substrate to connect the second circuitry to the conductive interconnection structure. Coupling the first circuitry and the second circuitry together includes: connecting the first circuitry and the second circuitry by the at least one of the one or more first conductive contacts and the corresponding one of the one or more second conductive contacts.

In some implementations, the memory array and the first circuitry are arranged in a first side of the first semiconductor structure along a first direction. The method further includes: forming a conductive interconnection structure on a second side of the first semiconductor structure that is opposite to the first side of the first semiconductor structure along a second direction perpendicular to the first direction. Forming one or more conductive structures extending in the first semiconductor structure from the conductive interconnection structure towards the first side of the second semiconductor structure. The first semiconductor structure includes a first conductive contact having a first end connected to a corresponding second conductive contact of the one or more second conductive contacts. Forming the one or more conductive structures extending in the first semiconductor structure includes: forming a corresponding conductive structure to be in contact with a second end of the first conductive contact that is opposite to the first end of the first conductive contact along the second direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a block diagram of an example system having one or more semiconductor devices.

FIG. 2 illustrates a block diagram of an example memory device.

FIG. 3 illustrates a top view of an example of a memory bank array.

FIGS. 4A-4B illustrate cross-section simplified views of example integrated semiconductor devices.

FIG. 5A illustrates a cross-section view of an example of a first semiconductor structure.

FIG. 5B illustrates a top view of an example of an embedded DRAM cell array.

FIG. 5C illustrates a cross-section view of an example of embedded DRAM cells.

FIG. 6 illustrates a cross-section view of an example of a second semiconductor structure.

FIG. 7A illustrates a cross-section view of an example of a semiconductor device with direct bonding.

FIG. 7B illustrates a cross-section view of an example of a semiconductor device with direct bonding and a conductive interconnection structure.

FIG. 8 illustrates a cross-section view of an example of a semiconductor device with hybrid bonding.

FIG. 9 illustrates a cross-section view of another example of a semiconductor device with hybrid bonding.

FIG. 10 is a flowchart chart of an example process for forming a semiconductor device.

Like reference numbers and designations in the various drawings indicate like elements. It is also to be understood that the various exemplary implementations shown in the figures are merely illustrative representations and are not necessarily drawn to scale.

### DETAILED DESCRIPTION

One crucial aspect of memory devices is their storage density, which refers to the amount of data that can be stored within a given physical area. Higher storage density is desirable because it allows for more information to be stored in a compact space. As technology advances, there is a constant push to increase storage density to meet the growing demands for data storage in various applications, such as consumer electronics, data centers, and mobile devices. A memory device can include memory arrays and peripheral circuitry. Memory arrays are organized structures of memory cells where data can be stored. Peripheral circuitry is configured to control the operations, e.g., reading and writing, of these memory arrays. The peripheral circuitry can be positioned in the areas between adjacent memory arrays and/or around the periphery of the multiple memory arrays. Increasing memory storage density can be challenging due to physical limitations, electrical interference, manufacturing difficulties, etc.

Implementations of the present disclosure provide methods, device, systems, and techniques for managing peripheral circuitries in semiconductor devices. In some implementations, a semiconductor device includes a first semiconductor structure which includes a memory array and a first circuitry coupled to the memory array. A second semiconductor structure includes a second circuitry. The first semiconductor structure includes a first bonding layer, and the second semiconductor structure includes a second bonding layer. The first bonding layer and the second bonding layer are in contact with each other. The first circuitry and the second circuitry are coupled together.

Implementations of the present disclosure can provide one or more of the following technical advantages and/or benefits. First, peripheral circuitries for controlling memory cell arrays can be divided into two parts, a first circuitry and a second circuitry. The first circuitry can be positioned in the areas between adjacent memory arrays and/or around the periphery of multiple memory arrays. The first circuitry can be manufactured together with memory arrays on a first semiconductor structure, while the second circuitry can be manufactured separately on the second semiconductor structure. Because a part of the peripherical circuitry (e.g., the second circuitry) is removed from the areas between adjacent memory arrays and/or around the periphery area of multiple memory arrays, the separation distance between neighboring memory arrays and/or their surrounding space is reduced. The reduced separation distance increases the memory cell capacity within a given lateral area. The first semiconductor structure and the second semiconductor structure can be subsequently bonded together vertically to electrically couple the first circuitry and the second circuitry. The first circuitry and the second circuitry can be configured to function together to manage and control the operations of memory arrays. This semiconductor device with two semiconductor structures can functionally perform the same memory array control task as a single semiconductor structure where the first circuitry and the second circuitry are formed together with the memory array.

Second, the first semiconductor structure and the second semiconductor structure can be manufactured separately on separate semiconductor substrates such that a limitation (e.g., thermal budget) of fabricating one of them does not limit the processes of fabricating another. High thermal budgets are often required for advanced manufacturing techniques, such as annealing processes in memory technologies. Because of enhanced thermal budget management, the techniques implemented herein give better control over the manufacturing processes, leading to improved yield and reduced variability in the performance of semiconductor devices.

Third, in contrast to the first semiconductor structure which includes both memory arrays and first circuitries, the second semiconductor structure can be configured to only include second circuitries without memory arrays, which may require less interconnection vias and/or conductive lines than the first semiconductor structure. This enables larger pitches for via or interconnection contacts in the second semiconductor structure, e.g., through-silicon-vias (TSV), through-silicon-contact (TSC), or other types of vias. This larger pitch contributes to a broader process window, which, in turn, simplifies the manufacturing process and reduces costs.

Fourth, a memory cell with buried word lines, e.g., buried DRAM or 6F2 DRAM cells, can be deployed with the techniques implemented herein. For buried DRAM cells, word lines, bit lines, and capacitors can be manufactured on one side of the semiconductor substrates. The first circuitries can be manufactured on the same side of the semiconductor substrate together with memory cell arrays. The advantage of burying the word lines in the substrate can include: reducing parasitic capacitance and improving the overall performance of the DRAM cell. Parasitic capacitance refers to unwanted capacitance that exists between conductive elements and can slow down the operation of the circuit. In addition, the channel length is increased in buried DRAM cells, allowing for better control of the flow of current between the source and drain terminals. The techniques enable the memory devices to achieve higher storage capacity and better device performance.

The techniques can enhance storage density of memory devices by separating peripheral circuitries into two parts. Different parts of peripheral circuitries can be manufactured on two semiconductor structures which are subsequently bonded together vertically. The techniques can reduce the lateral size of the memory devices and thus improve the storage density. In addition, different semiconductor structures can be manufactured separately on separate semiconductor substrates such that a limitation (e.g., thermal budget) of fabricating one of them does not limit the processes of fabricating another one. Further, process windows for vias and conductive interconnection lines can be improved due to the separation of peripheral circuitries. Enhanced process windows can contribute to higher yield rates, improved robustness, consistent performance, easier process control, and overall cost savings.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

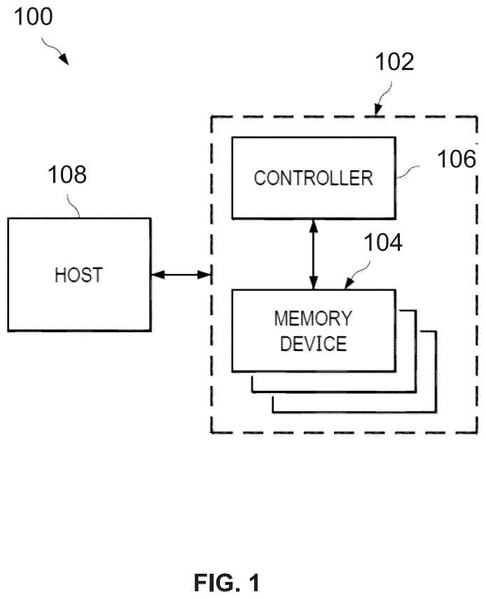

FIG. 1 illustrates a block diagram of an example system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive data to or from memory devices 104.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment solid state drives (SSDs) or embedded multi-media-cards (eMMCs) used as data storage for mobile devices, such as smartphones, tablets, laptop computers, etc., and enterprise storage arrays. Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, formatting memory device 104.

Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

In some implementations, the memory system 102 does not include the memory controller 106, and the host 108 is coupled to the memory device 104 directly. The memory controller 106 may be located in the host 108. Alternatively, the host 108 may not include the memory controller 106 either but may be configured to perform functions similar to what the memory controller 106 does as described above.

Memory device 104 can be any memory device disclosed in the present disclosure.

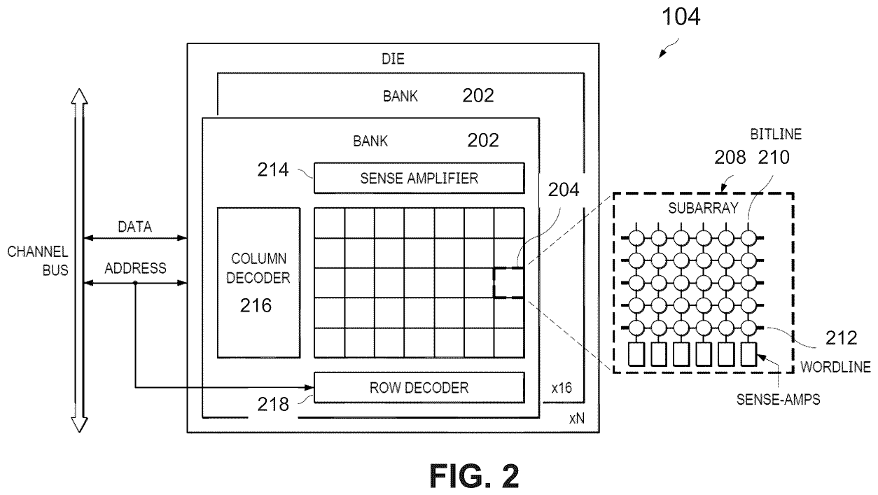

FIG. 2 illustrates a block diagram of an example memory device 104, according to some aspects of the present disclosure. The memory device 104 includes a set of memory banks 202. Each memory bank 202 includes a memory array 204 (also referred to as a memory cell array) having memory cells arranged in rows and columns. The memory array 204 may be divided into a number of memory sub-arrays 208 for efficient wiring and low power consumption. In some implementations, each or at least one of the memory cells includes a phase change memory (PCM) element. The PCM element may be programmed to either a set state or a reset state to store data as described above. Each memory cell is connected to a bit line 210 and a word line 212. Each memory bank 202 includes a data buffer/sense amplifier 214, a column decoder/bit line driver 216, and a row decoder/word line driver 218. In some examples, additional peripheral circuits not shown in FIG. 2 may be included as well.

Data buffer/sense amplifier 214 can be configured to read and program (write) data from and to memory cell array 204 according to control signals from a memory controller (e.g., the memory controller 106 of FIG. 1). In one example, data buffer/sense amplifier 214 may store one codeword of program data (write data) to be programmed into memory cell array 204. In another example, data buffer/sense amplifier 214 may perform program verify operations to ensure that the data has been properly programmed into select memory cells coupled to selected word lines 212. In yet another example, data buffer/sense amplifier 214 may also sense the low power signals from bit line 210 that represents a data bit stored in a memory cell and amplify the small voltage swing to recognizable logic levels in a read operation.

Column decoder/bit line driver 216 may be connected to the memory cell array 204 via bit lines and select/drive one or more bit lines to perform an operation on memory cell coupled to a selected bit line. Row decoder/word line driver 218 may be connected to the memory cell array 204 via word lines and select/drive one or more word lines to perform an operation on memory cell coupled to a selected word line. In some cases, when a particular row (word line) needs to be accessed for a read or write operation, the word line driver 218 can activate a word line by sending appropriate signals. Once the word line is activated, the memory cells connected to the word line become accessible for read or write operations. The specific operation performed on the memory cells can include reading the data stored in the cells or writing new data into them.

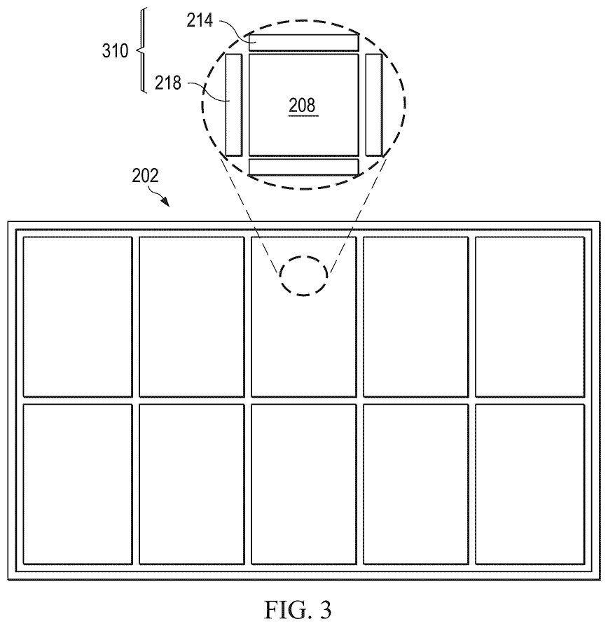

FIG. 3 illustrates a top view of an example of a memory bank array. As described above, each memory bank includes one or more memory subarrays 208. The memory subarrays 208 can be arranged close to each other to achieve higher compacity. Peripheral circuitries can be formed within the gap space separating two neighboring memory subarray 208 and used to control the operations of memory cells in the memory subarrays 208. In some implementations, the peripheral circuitry includes, without limitation to, sense amplifiers 214, word line drivers 218, input-output (I/O) circuitry, address decoders, row and column address buffers, read/write control logic, row and column decoders, clock generation and control, Error Correction Code (ECC) logic, power management circuitry, any combination thereof, or any other suitable circuitry.

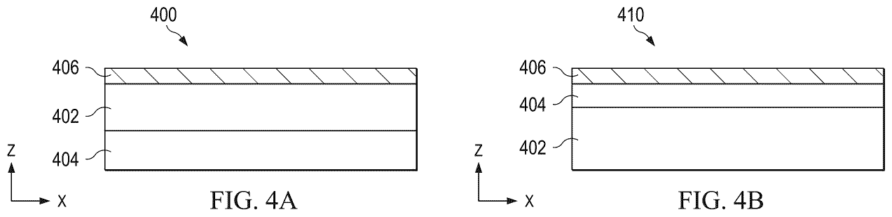

To achieve a higher memory cell capacity, the peripheral circuitry can be divided into two or more parts. In some implementations, only a first part of the peripheral circuitry is manufactured together with the memory subarrays 208 on a semiconductor substrate, as illustrated in FIG. 3. The remaining part of the peripheral circuitry are formed separately, e.g., on a separate semiconductor substrate. The remaining part of the peripheral circuitry are subsequently coupled with the first part of the peripheral circuitry through a bonding process, e.g., as described with further details in FIGS. 4A-4B. Multiple parts of the peripheral circuitry can function together to control and manage the operations of memory arrays.

In some implementations, as illustrated in FIG. 3, the first part of the peripheral circuitry can include sense amplifiers 214, which are configured to amplify the small signals read from memory cells to a level that can be reliably interpreted. Alternatively, or in addition, the first part of the peripheral circuitry includes word line drivers 218, which activate the appropriate word lines to enable the read or write operation on a specific memory cell. It is understood that the first part of peripheral circuitry can include, in addition, or alternatively, other suitable circuitries.

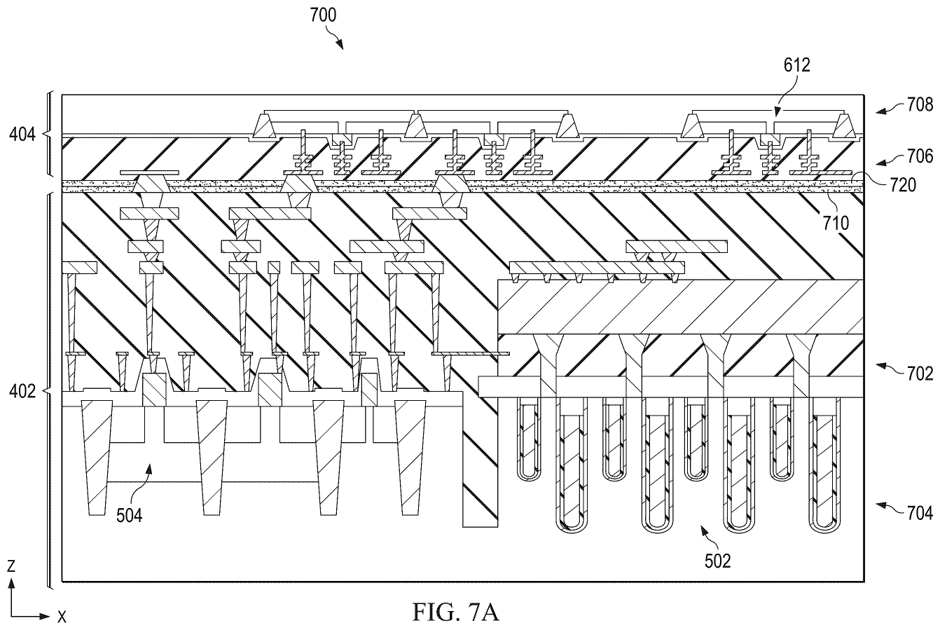

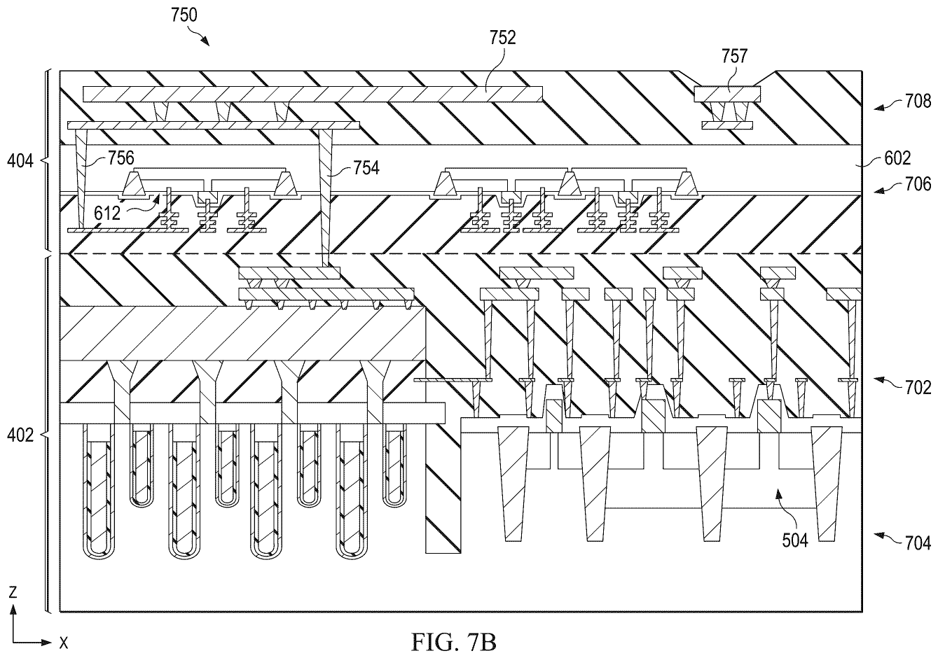

FIGS. 4A-4B illustrates cross-section simplified views of example integrated semiconductor devices 400, 410. As noted above, a peripheral circuitry can be divided into two parts, a first circuitry and a second circuitry. Memory arrays/subarrays and the first circuitry can be manufactured in a first semiconductor structure 402, while the second circuitry can be manufactured in the second semiconductor structure 404. In some implementations, the first semiconductor structure 402 and the second semiconductor structure 404 are manufactured separately on separate semiconductor substrates such that a limitation (e.g., thermal budget) of fabricating one of them does not limit the processes of fabricating another one. In some implementations, the semiconductor structures 402, 404 can be fabricated in parallel on a same substrate through a multi-chip design. In some implementations, the first semiconductor structure 402 and the second semiconductor structure 404 are integrated by direct bonding or hybrid bonding, as described with further details in FIGS. 7A-9.

In some implementations, the first circuitry includes one or more sense amplifiers 214 and/or one or more word line drivers 218. In some implementations, the second circuitry includes input-output (I/O) circuitry configured to communicate with one or more external devices. The first semiconductor structure 402 and the second semiconductor structure 404 can be integrated to establish a connection between the first circuitry and the second circuitry. The first circuitry and the second circuitry can function together to manage and control the operations of the memory arrays formed on the first semiconductor structure 402.

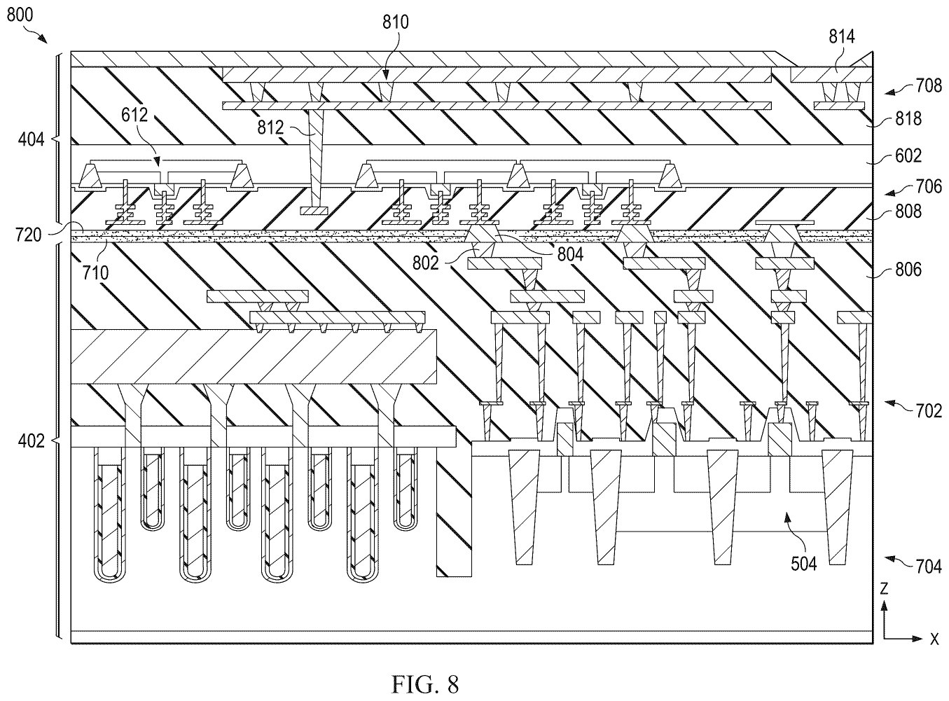

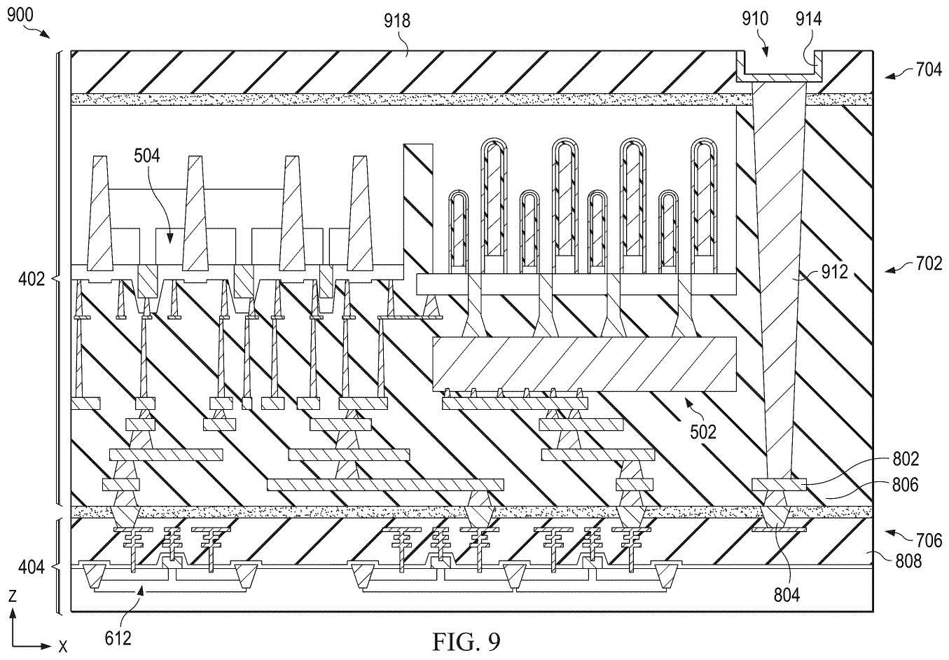

In some implementations, as illustrated in FIG. 4A, in the semiconductor device 400, the first semiconductor structure 402 is integrated on top of the second semiconductor structure 404. A conductive interconnection structure can be formed on the top of the first semiconductor structure 402 (e.g., as shown in FIG. 9). The conductive interconnection structure 406 can be used to establish the communication with external devices, e.g., a power source. In addition, or alternatively, the conductive interconnection structure 406 can be deployed with conductive contacts to connect the first circuitry in the first semiconductor structure 402 and the second circuitry in the second semiconductor structure 404. In some implementations, as illustrated in FIG. 4B, in the semiconductor device 410, a conductive interconnection structure 406 is formed on the top of the second semiconductor structure 404 (e.g., as shown in FIGS. 7B-8).

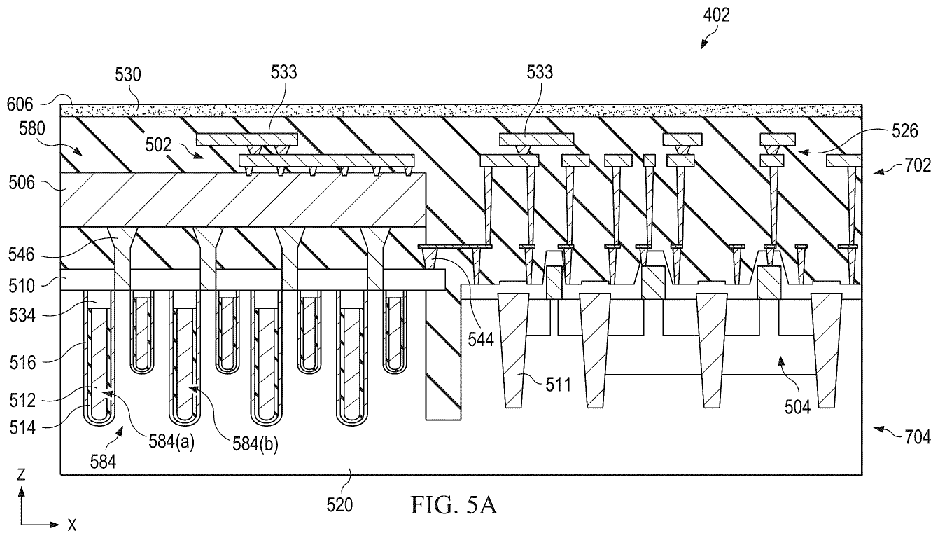

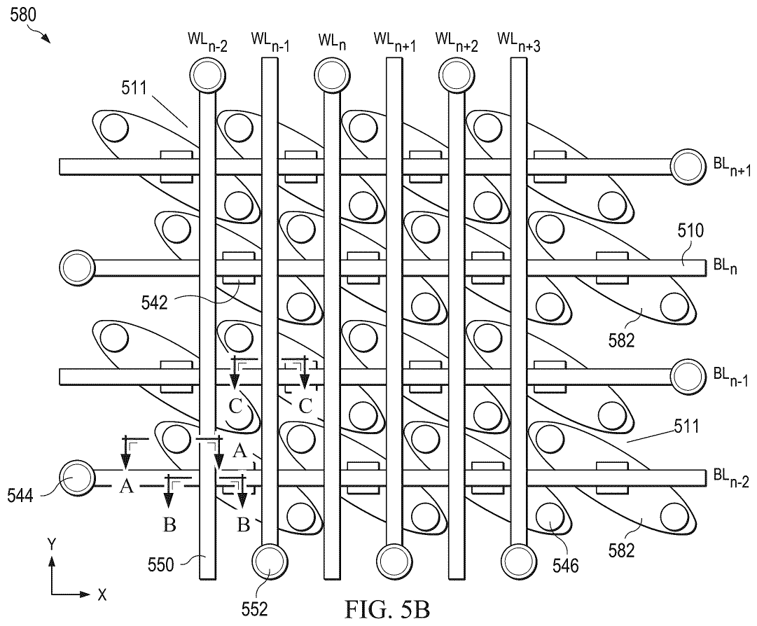

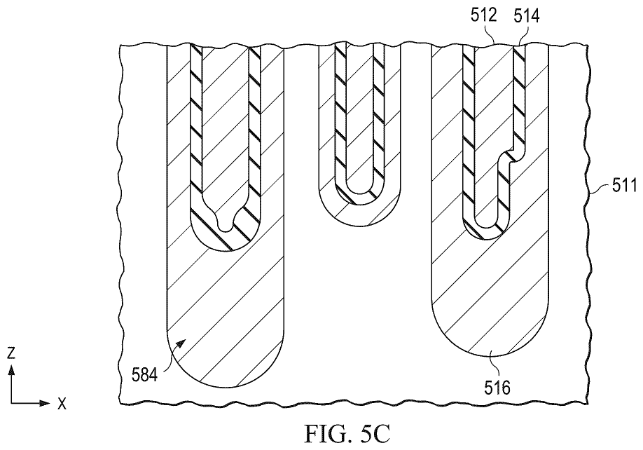

FIG. 5A illustrates a cross-section view of an example of a first semiconductor structure 402. FIG. 5B illustrates a top view of an example of an embedded DRAM cell array. FIG. 5C illustrates a cross-section view of a part of example embedded DRAM cells. As used herein, whether one component (e.g., a layer or a device) is “on,” “above,” or “below” another component (e.g., a layer or a device) of a semiconductor structure is determined relative to the substrate of the semiconductor structure (e.g., substrate 520) in the z-direction (i.e., the vertical direction) when the substrate is positioned in the lowest plane of the semiconductor structure in the z-direction.

The first semiconductor structure 402 can include a memory array 502 and a first circuitry 504. The memory array 502 can be one or more memory subarrays 208 in FIGS. 2-3. The first circuitry 504 can include sense amplifier 214 and/or word line driver 218 in FIGS. 2-3. In some implementations, as illustrated in FIG. 5A, the memory array 502 and the first circuitry 504 are arranged laterally along X axis on a substrate 520.

In some implementations, the memory array 502 includes an embedded DRAM cell array 580. An embedded DRAM cell array 580 can include a plurality of cell pairs. Referring to FIG. 5B, each pair of cells can be in an active area 582 in the substrate 520. In some implementations, the active area 582 of the substrate 520 is formed by implanting dopants into a semiconductor substrate. The dopants can include N+ type dopants (e.g., Phosphorus (P) or Arsenic (As)) or P− type dopants (e.g., Boron (B) or Gallium (Ga)) at a desired doping level.

The active area 582 can have a longitude axis oriented at an angle relative to the X axis. Each active area 582 can extend vertically along Z axis into the substrate 520 as illustrated in FIGS. 5A and 5C. FIG. 5C illustrates that each cell pair can be isolated from its neighboring cell pairs by shallow trench isolation (STI) 511 with one or more dielectric materials. The STI 511 can be formed on the silicon substrate 520 (silicon substrate not shown in FIG. 5C). FIG. 5A illustrates each cell pair can be isolated from each other by the silicon substrate 520, and the silicon substrate 520 can have different dopants or doping levels from the channels 516. In some implementations, each cell pair is isolated by LOCOS (localized oxidation of silicon) isolation or buried oxide (BOX) isolation.

Referring to FIG. 5B, each cell pair can include two cells which share a bit line contact 542 and thus connect to a same bit line 510. The bit line contact 542 is not shown in FIGS. 5A and 5C. Each cell includes a transistor 584 and a capacitor 506. The transistor 584 can include a drain terminal, a source terminal, and a gate. The capacitor 506 can be connected to a source terminal of the transistor 584 through the source contact 546 and used to store a charge. The charge represents a bit of information. The transistor 584 can be used as a switch for the capacitor 506. A source contact 546 connects the source terminal of the transistor 584 with a corresponding capacitor 506, as illustrated in FIG. 5A. The source contacts 546 for a cell pair can be distributed along the longitude axis of the active area 582, as illustrated in FIG. 5B. Although not shown in FIG. 5A, it is understood that each capacitor 506 is isolated from one another by dielectric materials. It is further understood that the capacitor 506 in FIG. 5A is for illustrative purposes only and doesn't accurately represent the true structures of capacitors. In some implementations, the source terminals or drain terminals of the transistors 584 are doped with N+ type dopants (e.g., Phosphorus (P) or Arsenic (As)) or P-type dopants (e.g., Boron (B) or Gallium (Ga)) at a desired doping level, or comprise Silicon Germanium (SiGe).

In some implementations, the gate 512 for a transistor 584 is surrounded by a U shape or a quasi-U shape gate dielectric layer 514, e.g., as illustrated in FIGS. 5A and 5C. Although FIG. 5C shows different shapes of gate dielectric layer 514 in adjacent memory cell pairs, it is understood that in a memory array 502 adjacent memory cell pairs can have same or similar shape of gate dielectric layer 514. The gate 512 can be part of a word line 550. The gate dielectric layer 514 can be surrounded by the channel materials (e.g., doped silicon). In other words, the gate 512, the gate dielectric layer 514, and the channels 516 can be arranged radially from the center toward the outer surface of each active area 582. Each active area 582 can be isolated from its neighboring active area by shallow trench isolation (STI) 511 with dielectric materials (as shown in FIG. 5C). In some implementations, the gate dielectric layer 514 of the transistor 584 includes a dielectric material, such as silicon oxide, silicon nitride, or high-k dielectrics including, but not limited to, Al2O3, HfO2, Ta2O5, ZrO2, TiO2, or any combination thereof. In some implementations, the gate 512 includes a conductive material including, but not limited to W, Co, Cu, Al, TiN, TaN, polysilicon, silicide, or any combination thereof.

A plurality of word lines 550 can be buried in the substrate 520 and extending through multiple active areas 582 along Y axis, e.g., as illustrated in FIG. 5B. In some implementations, a corresponding part of the word line 550 is utilized as a gate 512 for each transistor 584. The word line 550 controls the reading or writing operations of the memory cells. A plurality of bit lines 510 extends with an angle with respective to the word lines 550 and is disposed between the word lines 550 and the capacitors 506 along Z axis, e.g., as illustrated in FIG. 5A. In some implementations, the bit lines 510 are perpendicular to the word lines 550, e.g., as illustrated in FIG. 5B. In some implementations, the bit lines 510 are non-orthogonal to the word lines 550 (not shown). The advantages of burying the word lines in the substrate can include reducing parasitic capacitance and improving the overall performance of the DRAM cell. In addition, the channel length can be increased with buried word lines, allowing for better control of the flow of current between the source and drain terminals.

FIG. 5A illustrate relative positions of devices or structures in an example memory array 502 along Z direction. For example, the bit lines 510 are situated between the capacitors 506 and the transistors 584 along the Z direction. The gate 512, which is part of the word line 510, is embedded in the substrate 520. However, it is to be understood that that the devices or structures depicted in FIG. 5A can represent a composite view from multiple X-Z cross-sectional planes. Thus, FIG. 5A is for illustrative purpose only and does not depict a single cross-sectional view within an actual device. For example, the bit line 510 and the source contact 546 in FIG. 5A are in different X-Z cross-sectional planes. Referring to FIG. 5B, the bit line 510 can be in the cross-sectional plane B-B, while the source contact 546 can be in cross-sectional plane A-A. The bit line 510 and the source contact 546 are isolated by dielectric material along Y-direction, although such isolation is not shown in FIG. 5A. In another example, the transistor 584(a) and the transistor 584(b) in FIG. 5A can be in different X-Z cross-sectional planes. For example, as illustrated in FIG. 5B, the transistor 584(a) can be located in the cross-sectional plane B-B, while the transistor 584(b) can be located in cross-sectional plane C-C. Similar interpretations also apply to FIG. 5C. Individual transistor 584 in FIG. 5C can be in different X-Z cross-sectional planes.

Further, referring back to FIG. 5B, while the X-Y plane view shows intersecting bit lines 510 and word lines 550, an isolating material is situated between these two lines along the Z direction. As shown in FIG. 5A, the gate 512, which is part of the word line 550, is isolated from the bit line 510 by a dielectric material 534 along the Z direction.

Although not shown, it is understood that the memory array 502 can include any other types of memory cells, including without limitation to, NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others.

Each word line 550 can be connected to a word line pad 552 at one end, e.g., as illustrated in FIG. 5B. To realize a more compact configuration, the word line pads 552 can be arranged in opposite ends of adjacent word lines 550. For example, the word line contact for WLn-2 can be located on a positive end of the word line WLn-2 along a positive Y axis, while the word line pad 552 for WLn-1 can be located on a negative end of the word line along a negative Y axis. Likewise, the bit line pads 544 can also be arranged in opposite ends of adjacent bit lines 510 for a compact configuration.

As shown in FIG. 5A, the first semiconductor structure 402 has a first side 702 and a second side 704. The first side 702 can be along the positive Z direction, e.g., the front side of the substrate 520. The second side 704 is opposite to the first side along the negative Z direction, e.g., the back side of the substrate 520. In some implementations, the bit lines 510 and the capacitors 506 can be arranged on a same side of the word lines 550. For example, the bit lines 510 can be disposed between the word lines 550 and the capacitors 506 along Z axis. The word lines 550, bit lines 510 and the capacitors 506 can be formed consecutively on the first side 702 of the first semiconductor structure 402. This configuration can case the process complexity to manufacture control circuitries, e.g., first circuitry 504, which are configured to connect with the bit lines 510 and/or word lines 550, on the first side 702 of the first semiconductor structure 402.

In some implementations, the bit lines 510, the word lines 550, the bit line pads 544, or the word line pads 552 are made of a conductive material including, but not limited to W, Co, Cu, Al, TiN, TaN, doped polysilicon, or any combination thereof. In some implementations, the bit lines 510, the word lines 550, the bit line pads 544, or the word line pads 552 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

The first circuitry 504 can include a first part of a peripheral circuitry configured to manage and control some operations of memory cells. As noted above, in some implementations, the first circuitry 504 includes a sense amplifier 214 and/or a word line driver 218. The sense amplifier 214 can be connected to a bit line 510 through bit line pad 544, which is configured to amplify and detect the small voltage difference that represents the stored data in a memory cell. The word line driver 218 can be connected a word line 550, which is configured to activate and control the word lines 550 in a memory array during read and/or write operations. In some implementations, the first circuitry 504 is connected to the memory array 502 through metal routings, e.g., metal lines 533.

The first circuitry 504 can be a CMOS (Complementary Metal-Oxide-Semiconductor) circuitry, which can be built by transistors, capacitors, resistors, diodes, bipolar junctions, inductors, varactors, or a combination thereof. The transistors can include NMOS transistors, PMOS transistors, and/or bipolar junctions. An NMOS transistor can include an n-type semiconductor (source and drain) and a P-type substrate. A PMOS transistor can have a P-type semiconductor with an n-type substrate. Bipolar junctions can include NPN and PNP transistors. In an NPN transistor, a thin layer of P-type semiconductor is sandwiched between two layers of N-type semiconductor. In a PNP transistor, a thin layer of N-type semiconductor is sandwiched between two layers of P-type semiconductor. The combination of these transistors allows for complementary logic, where one is ON while the other is OFF. Transistors can be isolated by trenches. Trench isolations (e.g., shallow trench isolations (STIs) 511) and doped regions (e.g., wells, sources, and drains of transistors) can be formed on or in the substrate as well. The combination of these components allows for the creation of complex digital and analog circuits for memory array control.

In some implementations, the first semiconductor structure 402 further includes an interconnect layer 526 above the first circuitry 504 to transfer electrical signals to and from the first circuitry 504 and/or communicate with the memory array 502. The interconnect layer 526 can include a plurality of interconnects (also referred to herein as “contacts”), including lateral interconnect lines, e.g., metal lines, and VIA contacts. The interconnect layer 526 can further include one or more interlay dielectric (ILD) layers in which the interconnect lines and via contacts can form. That is, the interconnect layer 526 can include interconnect lines (e.g., metal lines 533) and via contacts in multiple ILD layers. In some implementations, transistors in the first circuitry 504 are coupled to one another through the interconnects in the interconnect layer 526. The interconnects in interconnect layer 526 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

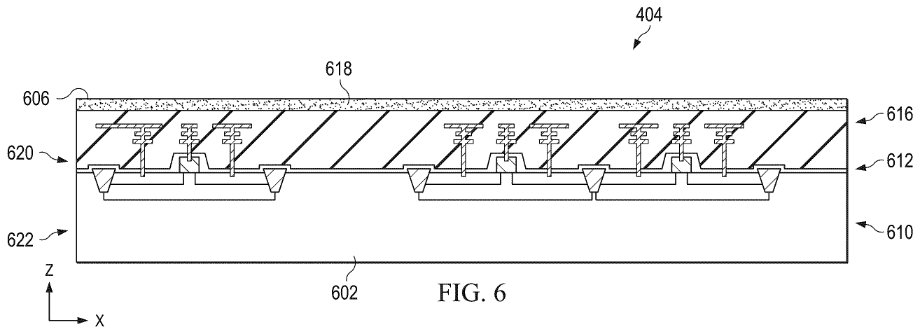

As shown in FIG. 5A, the first semiconductor structure 402 has a front side (e.g., the first side 702) and a back side (e.g., the second side 704). The first semiconductor structure 402 can include a bonding layer 530 at the first side 702 of the first semiconductor structure 402 and above the interconnect layer 526. In some implementations, as described with further details in FIGS. 8-9, the bonding layer 530 can include a plurality of bonding contacts and dielectrics electrically isolating the bonding contacts. The bonding contacts can include a conductive material, such as Cu. The remaining area of the bonding layer 530 can be formed with a dielectric material, such as silicon oxide. The bonding contacts and surrounding dielectric material in the bonding layer 530 can be used for hybrid bonding. Similarly, as described below in FIG. 6, the second semiconductor structure 404 can also include a bonding layer and/or bonding contacts at the bonding interface. In some implementations, the bonding layers are not separate layers deposited onto the semiconductor structures. Instead, the bonding layers can refer to the bonding interface with diffused atoms between two semiconductor structures after thermal treatment. In some implementations, the bonding layers can be separate layers for gluing.

In some implementations, the memory array 502 and the first circuitry 504 can be formed by a plurality of processes including, but not limited to, photolithography, dry/wet etch, thin film deposition, thermal growth, implantation, chemical mechanical polishing (CMP), and any other suitable processes. Dielectric material can be deposited using one or more thin film deposition processes, including, but not limited to, chemical vapor deposition (CVD), physical vapor deposition (PVD), atomic layer deposition (ALD), sputtering, or any combination thereof. Conductive material can be deposited by one or more thin film deposition processes including, but not limited to, CVD, PVD, ALD, Metal-Organic Chemical Vapor Deposition (MOCVD), sputtering, electroplating, electroless plating, clectron-beam evaporation, or any combination thereof. The etching can involve one or more dry etching and/or wet etching process, including, but not limited to, reactive ion etching (RIE), plasma etching, hydrofluoric acid (HF) etching, sputtering ctching, KOH Etching (Potassium Hydroxide), TMAH Etching (Tetramethylammonium Hydroxide), Buffered Oxide Etchant (BOE), Piranha Solution (H2SO4/H2O2), or any combination thereof.

FIG. 6 illustrates a cross-section view of an example of a second semiconductor structure 404. The second semiconductor structure 404 can include a substrate 602, which can include silicon (e.g., single crystalline silicon, c-Si), SiGe, GaAs, Ge, SOI, or any other suitable materials. The second semiconductor structure 404 includes a second circuitry 612 (e.g., the second part of the peripheral circuitries) on the substrate 602. In some implementations, the second circuitry 612 includes input-output (I/O) circuitry configured to communicate with one or more external devices. In some implementations, the second circuitry 612 includes address decoders, row and column address buffers, read/write control logic, row and column decoders, clock generation and control, Error Correction Code (ECC) logic, power management circuitry, any combination thereof, or any other suitable circuitry. The second circuitry 612 can be configured to function together with the first circuitry 504 to control and manage the operations of memory array 502.

In some implementations, the second circuitry 612 includes a plurality of transistors (e.g., planar transistors and/or 3D transistors). Trench isolations (e.g., shallow trench isolations (STIs)) and doped regions (e.g., wells, sources, and drains of transistors) can be formed on or in the substrate 602 as well. In some examples, the second circuitry 612 is formed using complementary metal-oxide-semiconductor (CMOS) technology, and the second semiconductor structure 404 can be also formed on a semiconductor die that can be referred to as a control die or a CMOS die.

In some implementations, the second semiconductor structure 404 further includes an interconnect layer 616 above the second circuitry 612 to transfer electrical signals to and from the second circuitry 612. The interconnect layer 616 can include a plurality of interconnects (also referred to herein as “contacts”), including lateral interconnect lines and VIA contacts. The interconnect layer 616 can further include one or more interlay dielectric (ILD) layers in which the interconnect lines and via contacts can form. That is, the interconnect layer 616 can include interconnect lines and via contacts in multiple ILD layers. In some implementations, the second circuitry 612 is coupled to one another through the interconnects in the interconnect layer 616. The interconnects in interconnect layer 616 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 6, the second semiconductor structure 404 has a front side 620 and a back side 622, and the second semiconductor structure 404 can further include a bonding layer 618 above the interconnect layer 616 and the second circuitry 612 in the front side 620.

In some implementations, the bonding layer 120 can include a plurality of bonding contacts, as described below in FIGS. 8-9 and a dielectric material electrically isolating the bonding contacts. The bonding contacts can include a conductive material, such as Cu. The remaining area of the bonding layer 618 can be formed with the dielectric material, such as silicon oxide. The bonding contacts and the surrounding dielectric material in the bonding layer can be used for hybrid bonding. The bonding contacts can be in contact with the bonding contacts of the first semiconductor structure at the bonding interface 606, as described below in FIGS. 8-9.

FIG. 7A illustrates a cross-section view of an example of an integrated semiconductor device 700 with direct bonding. In some implementations, the integration is conducted through a direct bonding technique. As shown in FIG. 7A, a first circuitry 504 and a first bonding layer 710 are in a first side 702 of a first semiconductor structure 402, and a second circuitry 612 and a second bonding layer 720 are in a first side 706 of a second semiconductor structure 404. The first side 702 of the first semiconductor structure 402 and the first side 706 of the second semiconductor structure 404 are bonded with the first bonding layer 710 being in contact with the second bonding layer 720. In some implementations, the first and second bonding layers 710 and 720 are not separate layers deposited onto the semiconductor structures 402, 404. In some examples, the bonding layers 710 and 720 can refer to a bonding interface with diffused atoms between two semiconductor structures 402, 404 after thermal treatment. In some implementations, the bonding layers 710 and 720 can be separate layers deposited onto the semiconductor structures 402, 404 for bonding, e.g., gluing.

In some implementations, the direct bonding involves oxide bonding. The surfaces of the two semiconductor structures can be prepared by cleaning the surfaces thoroughly to remove any contaminants and oxides. An oxide layer can be grown or deposited on the surfaces of the first side of the two semiconductor structures. In some examples, the oxide layer includes silicon dioxide (SiO2). The two semiconductor structures can be then aligned to have a proper match. The integrated semiconductor structures can be subjected to high-temperature annealing. During annealing, the oxide layer can become porous, and atoms at the interface can diffuse and rearrange, forming strong covalent bonds between the two semiconductor structures. After annealing, the bonded semiconductor structures can be gradually cooled down. This allows the formation of strong bonds between the semiconductor materials.

In some implementations, the direct bonding involves molecular or atomic bonding. The surfaces of the two semiconductor structures are prepared by cleaning the surfaces thoroughly to remove any contaminants and oxides. The two semiconductor structures are then aligned to have a proper match. The aligned semiconductor structures are brought into close contact. The van der Waals forces and other attractive forces between the atoms on the surfaces help to hold the semiconductor structures together. The bonded semiconductor structures are subjected to high-temperature annealing. This heat treatment can be done in a vacuum or controlled atmosphere to facilitate the migration of atoms at the interface and promote the formation of covalent bonds. After annealing, the bonded substrates are gradually cooled down. This allows the formation of strong bonds between the semiconductor materials.

FIG. 7B illustrates a cross-section view of an example of a semiconductor device 750 with a direct bonding and a conductive interconnection structure. As illustrated in FIG. 7B, the second semiconductor structure 404 includes a semiconductor substrate 602. The second circuitry 612 is on a first side 706 of the semiconductor substrate 602. The semiconductor device 750 further includes a conductive interconnection structure 752 on a second side 708 of the semiconductor substrate 602 that is opposite to the first side 706 of the semiconductor substrate 602. The first circuitry 504 is connected to the conductive interconnection structure 752 by a first conductive structure 754 extending through the semiconductor substrate 602, the first bonding layer (not shown), and the second bonding layer (not shown). The second circuitry 612 is connected to the conductive interconnection structure 752 by a second conductive structure 756 extending through the semiconductor substrate 602. The first conductive structure 754 and the second conductive structure 756 are connected by the conductive interconnection structure 752. In some implementations, the first conductive structure 754 and the second conductive structure 756 can be through-silicon-vias (TSV) or through-silicon-contact (TSC), which penetrate the silicon substrate of a semiconductor device, connecting different layers of the conductive layers or circuitries through the thickness of the silicon. TSV and/or TSC can be formed by etching or drilling small holes through the silicon substrate. These holes are then filled with conductive material (e.g., copper) to create the vertical interconnects.

In some implementations, the conductive interconnection structure 752 transfers electrical signals to and from the second circuitry 612. The conductive interconnection structure 752 can include a plurality of interconnects (also referred to herein as “contacts”), including lateral interconnect lines and VIA contacts. The conductive interconnection structure 752 can further include one or more interlay dielectric (ILD) layers in which the interconnect lines and via contacts can form. That is, the conductive interconnection structure 752 can include interconnect lines and via contacts in multiple ILD layers. In some implementations, the conductive interconnection structure 752 further includes a power source structure 757 as illustrated in FIG. 7B to power the semiconductor device 750. The power source structure 757 can also include a plurality of interconnects and VIA contacts.

The interconnects in the conductive interconnection structure 752 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof. The conductive interconnection structure 752 can be formed by a plurality of processes including, but not limited to, photolithography, dry/wet etch, thin film deposition, thermal growth, implantation, chemical mechanical polishing (CMP), and any other suitable processes. The dielectric structure can be deposited using one or more thin film deposition processes, including, but not limited to, chemical vapor deposition (CVD), physical vapor deposition (PVD), atomic layer deposition (ALD), sputtering, or any combination thereof. The first conductive structure 754, the second conductive structure 756 and the conductive interconnection structure 752 can be deposited by one or more thin film deposition processes including, but not limited to, CVD, PVD, ALD, Metal-Organic Chemical Vapor Deposition (MOCVD), sputtering, electroplating, electroless plating, clectron-beam evaporation, or any combination thereof. Etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

FIG. 8 illustrates a cross-section view of an example of a semiconductor device 800 with hybrid bonding. In some implementations, the integration of two semiconductor structures can be formed by a hybrid bonding. A hybrid bonding can include a combination of metal-to-metal bonding and a direct oxide bonding. For example, the first bonding layer 710 includes one or more first conductive contacts 802 isolated by a first dielectric material 806. The first conductive contacts 802 are electrically connected to the first circuitry 504. The second bonding layer 720 includes one or more second conductive contacts 804 isolated by a second dielectric material 808. The second conductive contacts 804 are electrically connected to the second circuitry 612. At least one of the first conductive contacts 802 is in contact with a corresponding one second conductive contact 804, as illustrated in FIG. 8.

In some implementations, the second semiconductor structure 404 includes a semiconductor substrate 602. The second circuitry 612 is on a first side 706 of the semiconductor substrate 602. The semiconductor device 800 further includes a conductive interconnection structure 810 on a second side 708 of the semiconductor substrate 602 that is opposite to the first side 706 of the semiconductor substrate 602 along Z axis. The second circuitry 612 is connected to the conductive interconnection structure 810 by a conductive structure 812 extending through the semiconductor substrate 602. The first circuitry 504 and the second circuitry 612 are connected by the first conductive contacts 802 and the corresponding second conductive contacts 804. Therefore, the conductive interconnection structure 810 is electrically connected to both the first circuitry 504 and the second circuitry 612 through the conductive structure 812 and conductive contacts 802, 804. The conductive interconnection structure 810 can be deployed to control the operations of both circuitries 504, 612. In some implementations, the conductive structure 812 can include a through-silicon-vias (TSV) or through-silicon-contact (TSC).

In some implementations, the conductive interconnection structure 810 transfers electrical signals to and from the second circuitry 612. As the second circuitry 612 is coupled with the first circuitry 504, the conductive interconnection structure 810 can also transfer electrical signals to and from the first circuitry 504. The conductive interconnection structure 810 can include a plurality of interconnects (also referred to herein as “contacts”), including lateral interconnect lines, e.g., metal lines, and VIA contacts. The conductive interconnection structure 810 can further include one or more interlay dielectric (ILD) layers 818 in which the interconnect lines and via contacts can form. That is, the conductive interconnection structure 810 can include interconnect lines and via contacts in multiple ILD layers 818. In some implementations, the conductive interconnection structure 810 further includes a power source structure 814 as illustrated in FIG. 8, which connects to an external power source to power the semiconductor device 800. The power source structure 814 can also include a plurality of interconnects and VIA contacts.

The interconnects in conductive interconnection structure 810 and the conductive structure 812 can include conductive materials including, but not limited to, W, Co, Cu, Al, doped silicon, silicides, or any combination thereof. The ILD layers 818, the first dielectric material 806 and/or the second dielectric material 808 can be formed with dielectric materials including, but not limited to, silicon oxide, silicon nitride, silicon oxynitride, low-k dielectrics, or any combination thereof. The conductive structure 812 and the conductive interconnection structure 810 can be formed by a plurality of processes including, but not limited to, photolithography, dry/wet etch, thin film deposition, thermal growth, implantation, chemical mechanical polishing (CMP), and any other suitable processes. The dielectric structure, e.g., ILD layers 818, the first dielectric material 806 and/or the second dielectric material 808, can be deposited using one or more thin film deposition processes, including, but not limited to, chemical vapor deposition (CVD), physical vapor deposition (PVD), atomic layer deposition (ALD), sputtering, or any combination thereof. The conductive structure 812 and the conductive interconnection structure 810 can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof. Etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

FIG. 9 illustrates a cross-section view of an example of a semiconductor device 900 with hybrid bonding. For the semiconductor device 900, as illustrated in FIG. 9, the memory array 502 and the first circuitry 504 are arranged in the first side 702 of the first semiconductor structure 402 along X axis. The semiconductor device 900 includes a conductive interconnection structure 910 on a second side 704 of the first semiconductor structure 402 that is opposite to the first side 702 of the first semiconductor structure 402 along Z axis. One or more conductive structures 912 extend in the first semiconductor structure 402 from the conductive interconnection structure 910 towards the first side 706 of the second semiconductor structure 404. In some implementations, the conductive structure 912 can be through-silicon-vias (TSV) or through-silicon-contact (TSC).

In some implementations, the semiconductor device 900 deploys a hybrid bonding as described above. The conductive contacts (802, 804) electrically couple the first circuitry 504 and the second circuitry 612 together. One end of the conductive structure 912 can be electrically connected with the conductive interconnection structure 910. The other end of the conductive structure 912 can be electrically connected with at least one of the first conductive contacts 802. A first conductive contact 802 can be connected to a corresponding second conductive contact 804. Therefore, the conductive interconnection structure 910 can be electrically coupled to the first circuitry 504 and the second circuitry 612 through the conductive structure 912 and conductive contacts 802, 804. The conductive interconnection structure 910 can thus be deployed to control the operations of the first circuitry 504 and the second circuitry 612.

In some implementations, the conductive interconnection structure 910 transfers electrical signals to and from the first circuitry 504 and the second circuitry 612. Although not shown, the conductive interconnection structure 910 can include a plurality of interconnects (also referred to herein as “contacts”), including lateral interconnect lines (not shown) and VIA contacts. The conductive interconnection structure 910 can further include one or more interlay dielectric (ILD) layers 918 in which the interconnect lines and via contacts can form. That is, the conductive interconnection structure 910 can include interconnect lines and via contacts in multiple ILD layers. In some implementations, the conductive interconnection structure 910 includes a power source structure 914 as illustrated in FIG. 9, which connects to an external power source to power the semiconductor device 900. The power source structure 914 can also include a plurality of interconnects and VIA contacts (not shown).

The interconnects in conductive interconnection structure 910 and the conductive structures 912 can include conductive materials including, but not limited to, W, Co, Cu, Al, doped silicon, silicides, or any combination thereof. The ILD layers 918 can be formed with dielectric materials including, but not limited to, silicon oxide, silicon nitride, silicon oxynitride, low-k dielectrics, or any combination thereof. The conductive interconnection structure 910, the conductive structure 912 and conductive contacts (802, 804) can be formed by a plurality of processes including, but not limited to, photolithography, dry/wet etch, thin film deposition, thermal growth, implantation, chemical mechanical polishing (CMP), and any other suitable processes. The dielectric structure, e.g., the ILD layers 918, can be deposited using one or more thin film deposition processes, including, but not limited to, chemical vapor deposition (CVD), physical vapor deposition (PVD), atomic layer deposition (ALD), sputtering, or any combination thereof. The conductive interconnection structure 910, the conductive structure 912 and conductive contacts (802, 804) can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof. Etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

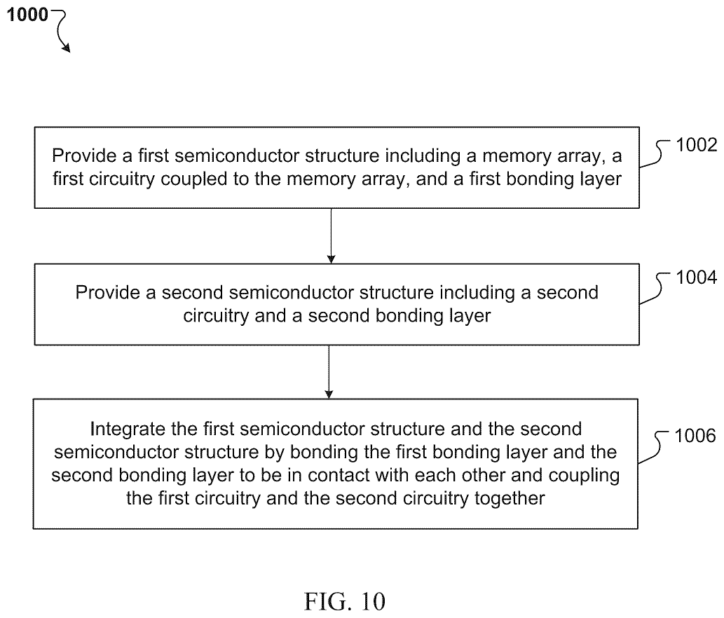

FIG. 10 is a flowchart chart of an example process 1000 for forming a semiconductor device. The semiconductor device can be, e.g., the memory device 104 of FIG. 1, the semiconductor device 400 or 410 of FIGS. 4A-4B, the semiconductor device 700 of FIG. 7A, the semiconductor device 750 of FIG. 7B, the semiconductor device 800 of FIG. 8, or the semiconductor device 900 of FIG. 9.

At step 1002, a first semiconductor structure is provided. The first semiconductor device includes a memory array, a first circuitry coupled to the memory array, and a first bonding layer. The first semiconductor structure can be, e.g., the first semiconductor structure 402 of any one of FIGS. 4A-5C and 7A-9. The memory array can be, e.g., the memory subarray 208 of FIGS. 2-3, or the memory array 502 of FIGS. 5A-5C, and 7A-9. The first circuitry can be, e.g., the first circuitry 310 of FIG. 3, or the first circuitry 504 of FIGS. 5A and 7A-9. The first bonding layer can be, e.g., the bonding layer 530 of FIG. 5A, or the first bonding layer 710 of FIGS. 7A-9.

At step 1004, a second semiconductor structure is provided. The semiconductor structure includes a second circuitry and a second bonding layer. The second semiconductor structure can be, e.g., the second semiconductor structure 404 of any one of FIGS. 4, 6 and 7A-9. The second circuitry can be, e.g., the second circuitry 612 of any one of FIGS. 6-9. The second bonding layer can be, e.g., the second bonding layer 618 of FIG. 6 or the second bonding layer 720 of FIGS. 7A-9.

At step 1006, the first semiconductor structure and the second semiconductor structure are integrated by bonding the first bonding layer and the second bonding layer to be in contact with each other. The first circuitry and the second circuitry are coupled together.

In some implementations, the first bonding layer includes one or more first conductive contacts isolated by a first dielectric material, and the second bonding layer includes one or more second conductive contacts isolated by a second dielectric material. At least one of the one or more first conductive contacts is in contact with a corresponding one of the one or more second conductive contacts. The first conductive contacts can be, e.g., the first conductive contact 802 of FIGS. 8-9. The second conductive contacts can be, e.g., the second conductive contacts 804 of FIGS. 8-9. The first dielectric material can be, e.g., the first dielectric material 806 of FIGS. 8-9. The second dielectric material can be, e.g., the second dielectric material 808 of FIGS. 8-9.

In some implementations, the second semiconductor structure includes a semiconductor substrate, and the second circuitry is formed on a first side of the semiconductor substrate. A conductive interconnection structure is formed on a second side of the semiconductor substrate that is opposite to the first side of the semiconductor substrate. A first conductive structure is formed extending through the semiconductor substrate, the first bonding layer, and the second bonding layer to connect the first circuitry to the conductive interconnection structure. A second conductive structure is formed extending through the semiconductor substrate to connect the second circuitry to the conductive interconnection structure. The first circuitry and the second circuitry are coupled together by connecting the first conductive structure and the second conductive structure through the conductive interconnection structure. The first side of the semiconductor substrate can be, the first side 702 of the first semiconductor structure 402 of FIGS. 7B-9, the first side 706 of the second semiconductor structures 404 of FIGS. 7B-9. The second side of the semiconductor substrate can be, the second side 704 of the first semiconductor structure 402 of FIGS. 7B-9, the second side 708 of the second semiconductor structures 404 of FIGS. 7B-9. The conductive interconnection structure can be, e.g., the conductive interconnection structure 752 of FIG. 7B, the conductive interconnection structure 810 of FIG. 8, or the conductive interconnection structure 910 of FIG. 9. The first conductive structure can be, e.g., the first conductive structure 754 of FIG. 7B, the conductive structure 812 of FIG. 8, or the conductive structure 912 of FIG. 9. The second conductive structure can be, e.g., the second conductive structure 756 of FIG. 7B, the conductive structure 812 of FIG. 8, or the conductive structure 912 of FIG. 9.

In some implementations, the second semiconductor structure includes a semiconductor substrate, and the second circuitry is on a first side of the semiconductor substrate. In addition, a conductive interconnection structure can be formed on a second side of the semiconductor substrate that is opposite to the first side of the semiconductor substrate. A conductive structure can be formed extending through the semiconductor substrate to connect the second circuitry to the conductive interconnection structure. The first circuitry and the second circuitry can be coupled together by connecting the first circuitry and the second circuitry by the at least one of the one or more first conductive contacts and the corresponding one of the one or more second conductive contacts. The first side of the semiconductor substrate can be, the first side 702 of the first semiconductor structure 402 of FIGS. 7B-9, the first side 706 of the second semiconductor structures 404 of FIGS. 7B-9. The second side of the semiconductor substrate can be, the second side 704 of the first semiconductor structure 402 of FIGS. 7B-9, the second side 708 of the second semiconductor structures 404 of FIGS. 7B-9. The conductive interconnection structure can be, e.g., the conductive interconnection structure 752 of FIG. 7B, the conductive interconnection structure 810 of FIG. 8, or the conductive interconnection structure 910 of FIG. 9. The first conductive structure can be, e.g., the first conductive structure 754 of FIG. 7B, the conductive structure 812 of FIG. 8, or the conductive structure 912 of FIG. 9. The second conductive structure can be, e.g., the second conductive structure 756 of FIG. 7B, the conductive structure 812 of FIG. 8, or the conductive structure 912 of FIG. 9. The first conductive contacts can be, e.g., the first conductive contact 802 of FIGS. 8-9. The second conductive contacts can be, e.g., the second conductive contacts 804 of FIGS. 8-9.

In some implementations, the memory array and the first circuitry are arranged in a first side of the first semiconductor structure along a first direction. A conductive interconnection structure is formed on a second side of the first semiconductor structure that is opposite to the first side of the first semiconductor structure along a second direction perpendicular to the first direction. One or more conductive structures are formed extending in the first semiconductor structure from the conductive interconnection structure towards the first side of the second semiconductor structure. The first semiconductor structure includes a first conductive contact having a first end connected to a corresponding second conductive contact of the one or more second conductive contacts. A corresponding conductive structure is in contact with a second end of the first conductive contact that is opposite to the first end of the first conductive contact along the second direction. The first side of the semiconductor substrate can be, the first side 702 of the first semiconductor structure 402 of FIGS. 7B-9, the first side 706 of the second semiconductor structures 404 of FIGS. 7B-9. The second side of the semiconductor substrate can be, the second side 704 of the first semiconductor structure 402 of FIGS. 7B-9, the second side 708 of the second semiconductor structures 404 of FIGS. 7B-9. The conductive interconnection structure can be, e.g., the conductive interconnection structure 752 of FIG. 7B, the conductive interconnection structure 810 of FIG. 8, or the conductive interconnection structure 910 of FIG. 9. The first conductive structure can be, e.g., the first conductive structure 754 of FIG. 7B, the conductive structure 812 of FIG. 8, or the conductive structure 912 of FIG. 9. The second conductive structure can be, e.g., the second conductive structure 756 of FIG. 7B, the conductive structure 812 of FIG. 8, or the conductive structure 912 of FIG. 9. The first conductive contacts can be, e.g., the first conductive contact 802 of FIGS. 8-9. The second conductive contacts can be, e.g., the second conductive contacts 804 of FIGS. 8-9.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first semiconductor structure comprising a memory array and a first circuitry coupled to the memory array; and
a second semiconductor structure comprising a second circuitry,
wherein the first semiconductor structure comprises a first bonding layer and the second semiconductor structure comprises a second bonding layer, and wherein the first bonding layer and the second bonding layer are in contact with each other, and
wherein the first circuitry and the second circuitry are coupled together.

2. The semiconductor device of claim 1, wherein the first circuitry and the first bonding layer are in a first side of the first semiconductor structure, and the second circuitry and the second bonding layer are in a first side of the second semiconductor structure.

3. The semiconductor device of claim 2, wherein the second semiconductor structure comprises a semiconductor substrate, and the second circuitry is on a first side of the semiconductor substrate,
wherein the semiconductor device further comprises a conductive interconnection structure on a second side of the semiconductor substrate that is opposite to the first side of the semiconductor substrate,
wherein the first circuitry is connected to the conductive interconnection structure by a first conductive structure extending through the semiconductor substrate, the first bonding layer, and the second bonding layer, and wherein the second circuitry is connected to the conductive interconnection structure by a second conductive structure extending through the semiconductor substrate, and
wherein the first conductive structure and the second conductive structure are connected by the conductive interconnection structure.

4. The semiconductor device of claim 2, wherein the first bonding layer comprises one or more first conductive contacts isolated by a first dielectric material, and the second bonding layer comprises one or more second conductive contacts isolated by a second dielectric material, and
wherein at least one of the one or more first conductive contacts is in contact with a corresponding one of the one or more second conductive contacts.

5. The semiconductor device of claim 4, wherein the second semiconductor structure comprises a semiconductor substrate, and the second circuitry is on a first side of the semiconductor substrate,
wherein the semiconductor device further comprises a conductive interconnection structure on a second side of the semiconductor substrate that is opposite to the first side of the semiconductor substrate,
wherein the second circuitry is connected to the conductive interconnection structure by a conductive structure extending through the semiconductor substrate, and
wherein the first circuitry and the second circuitry are connected by the at least one of the one or more first conductive contacts and the corresponding one of the one or more second conductive contacts.

6. The semiconductor device of claim 4, wherein the memory array and the first circuitry are arranged in the first side of the first semiconductor structure along a first direction,
wherein the semiconductor device further comprises:
a conductive interconnection structure on a second side of the first semiconductor structure that is opposite to the first side of the first semiconductor structure along a second direction perpendicular to the first direction, and
one or more conductive structures extending in the first semiconductor structure from the conductive interconnection structure towards the first side of the second semiconductor structure.

7. The semiconductor device of claim 6, wherein the first semiconductor structure comprises a first conductive contact having a first end connected to a corresponding second conductive contact of the one or more second conductive contacts and a second end connected to a corresponding conductive structure of the one or more conductive structures.

8. The semiconductor device of claim 1, wherein a memory cell of the memory array comprises a transistor and a capacitor,
wherein the transistor comprises a gate as at least part of a word line, a first terminal coupled to a bit line, and a second terminal coupled to the capacitor, and
wherein the bit line and the capacitor are on a same side of the word line.

9. The semiconductor device of claim 1, wherein the first circuitry comprises at least one of a sense amplifier coupled to a corresponding bit line or a word line driver coupled to a corresponding word line, and
wherein the second circuitry comprises an input-output (I/O) circuitry configured to communicate with one or more external devices.

10. A semiconductor device, comprising:
a first semiconductor structure comprising a memory array and a first circuitry coupled to the memory array; and
a second semiconductor structure comprising a second circuitry,
wherein the first circuitry and the second circuitry are coupled together, and
wherein a memory cell of the memory array comprises a transistor and a capacitor, wherein the transistor comprises a gate as at least part of a word line, a first terminal coupled to a bit line, and a second terminal coupled to the capacitor, and wherein the bit line and the capacitor are on a same side of the word line.

11. The semiconductor device of claim 10, wherein the first semiconductor structure comprises a first bonding layer and the second semiconductor structure comprises a second bonding layer,
wherein the first circuitry and the first bonding layer are in a first side of the first semiconductor structure, and the second circuitry and the second bonding layer are in a first side of the second semiconductor structure,
wherein the first bonding layer and the second bonding layer are in contact with each other, and
wherein the first bonding layer, the bit line, and the capacitor are on the same side of the word line.

12. The semiconductor device of claim 11, wherein the second semiconductor structure comprises a semiconductor substrate, and the second circuitry is on a first side of the semiconductor substrate,
wherein the semiconductor device further comprises a conductive interconnection structure on a second side of the semiconductor substrate that is opposite to the first side of the semiconductor substrate,
wherein the first circuitry is connected to the conductive interconnection structure by a first conductive structure extending through the semiconductor substrate, the first bonding layer, and the second bonding layer, and wherein the second circuitry is connected to the conductive interconnection structure by a second conductive structure extending through the semiconductor substrate, and
wherein the first conductive structure and the second conductive structure are connected by the conductive interconnection structure.

13. The semiconductor device of claim 11, wherein the first bonding layer comprises one or more first conductive contacts isolated by a first dielectric material, and the second bonding layer comprises one or more second conductive contacts isolated by a second dielectric material, and
wherein at least one of the one or more first conductive contacts is in contact with a corresponding one of the one or more second conductive contacts.

14. The semiconductor device of claim 13, wherein the second semiconductor structure comprises a semiconductor substrate, and the second circuitry is on a first side of the semiconductor substrate,
wherein the semiconductor device further comprises a conductive interconnection structure on a second side of the semiconductor substrate that is opposite to the first side of the semiconductor substrate,
wherein the second circuitry is connected to the conductive interconnection structure by a conductive structure extending through the semiconductor substrate, and
wherein the first circuitry and the second circuitry are connected by the at least one of the one or more first conductive contacts and the corresponding one of the one or more second conductive contacts.

15. The semiconductor device of claim 13, wherein the memory array and the first circuitry are arranged in the first side of the first semiconductor structure along a first direction,
wherein the semiconductor device further comprises:
a conductive interconnection structure on a second side of the first semiconductor structure that is opposite to the first side of the first semiconductor structure along a second direction perpendicular to the first direction, and
one or more conductive structures extending in the first semiconductor structure from the conductive interconnection structure towards the first side of the second semiconductor structure.

16. A method for forming a semiconductor device, the method comprising:
providing a first semiconductor structure comprising a memory array and a first circuitry coupled to the memory array, wherein the first semiconductor structure comprises a first bonding layer;
providing a second semiconductor structure comprising a second circuitry,
wherein the second semiconductor structure comprises a second bonding layer; and
integrating the first semiconductor structure and the second semiconductor structure by bonding the first bonding layer and the second bonding layer to be in contact with each other and coupling the first circuitry and the second circuitry together.

17. The method of claim 16, wherein the second semiconductor structure comprises a semiconductor substrate, and the second circuitry is formed on a first side of the semiconductor substrate,
wherein the method further comprises:
forming a conductive interconnection structure on a second side of the semiconductor substrate that is opposite to the first side of the semiconductor substrate;
forming a first conductive structure extending through the semiconductor substrate, the first bonding layer, and the second bonding layer to connect the first circuitry to the conductive interconnection structure; and
forming a second conductive structure extending through the semiconductor substrate to connect the second circuitry to the conductive interconnection structure,
wherein coupling the first circuitry and the second circuitry together comprises:
connecting the first conductive structure and the second conductive structure through the conductive interconnection structure.

18. The method of claim 16, wherein the first bonding layer comprises one or more first conductive contacts isolated by a first dielectric material, and the second bonding layer comprises one or more second conductive contacts isolated by a second dielectric material, and
wherein at least one of the one or more first conductive contacts is in contact with a corresponding one of the one or more second conductive contacts.

19. The method of claim 18, wherein the second semiconductor structure comprises a semiconductor substrate, and the second circuitry is on a first side of the semiconductor substrate,
wherein the method further comprises:
forming a conductive interconnection structure on a second side of the semiconductor substrate that is opposite to the first side of the semiconductor substrate; and
forming a conductive structure extending through the semiconductor substrate to connect the second circuitry to the conductive interconnection structure,
wherein coupling the first circuitry and the second circuitry together comprises:
connecting the first circuitry and the second circuitry by the at least one of the one or more first conductive contacts and the corresponding one of the one or more second conductive contacts.

20. The method of claim 18, wherein the memory array and the first circuitry are arranged in a first side of the first semiconductor structure along a first direction,
wherein the method further comprises:
forming a conductive interconnection structure on a second side of the first semiconductor structure that is opposite to the first side of the first semiconductor structure along a second direction perpendicular to the first direction; and
forming one or more conductive structures extending in the first semiconductor structure from the conductive interconnection structure towards the first side of the second semiconductor structure,
wherein the first semiconductor structure comprises a first conductive contact having a first end connected to a corresponding second conductive contact of the one or more second conductive contacts, and
wherein forming the one or more conductive structures extending in the first semiconductor structure comprises:
forming a corresponding conductive structure to be in contact with a second end of the first conductive contact that is opposite to the first end of the first conductive contact along the second direction.
